(19) United States
(12) Patent Application Publication
(10) Pub. No.: US 2011/0297422 A1
(43) Pub. Date: Dec. 8, 2011

(54) Circuit board and apparatus for processing defect in circuit board

(75) Inventors: Su Hwan Cho, Seoul (KR); Sung Eun Kim, Suwon (KR); Kyoung Jin Jeong, Suwon (KR)

(73) Assignee: SAMSUNG ELECTRO-MECHANICS CO., LTD., Suwon (KR)

(21) Appl. No.: 12/926,197

(22) Filed: Nov. 1, 2010

(30) Foreign Application Priority Data
Jun. 4, 2010 (KR) 10-2010-0052732

(51) Int. Cl. H05K 1/00; G01N 19/00; H05K 1/09

(52) U.S. Cl. 174/250; 174/257; 73/865.8

(57) ABSTRACT

Provided are a circuit board and an apparatus for processing a defect in a circuit board. The circuit board includes at least one non-defective cell including a non-defective circuit pattern, at least one defective cell including a defective circuit pattern, and a short line printed on the circuit pattern of the at least one defective cell.

### CROSS-REFERENCE TO RELATED APPLICATIONS

This application claims the priority of Korean Patent Application No. 10-2010-0052732 filed on Jun. 4, 2010, in the Korean Intellectual Property Office, the disclosure of which is incorporated herein by reference.

### BACKGROUND OF THE INVENTION

1. Field of the Invention

The present invention relates to a circuit board and an apparatus for processing a defect in a circuit board, and more particularly, to a circuit board, and an apparatus for processing a defect in a circuit board, capable of realizing improved accuracy in detecting a defective cell by printing a short line in the main wiring of a defective cell on a circuit board by using an inkjet printing method.

2. Description of the Related Art

In general, Printed Circuit Boards (PCB) for electronic circuits include various components, such as chips or devices, mounted on an insulating substrate, and circuit patterns are formed thereon with regard to the mounted components.

Such PCBs are mass-produced by automated production lines, and foreign bodies, generated in production facilities, may bring about open circuit patterns, defective pattern widths or the like. For this reason, the process of detecting defective cells is carried out.

As for the process of detecting defective cells on a PCB, a PCB, having a plurality of cells arrayed thereon, is subjected to an Automatic Optical Inspection (AOI). A circuit pattern in a cell, which is determined to be defective by the AOI, is scratched manually by an operator in order to open the wiring thereof and thereby indicate a defect. Subsequently, E-checking is carried out to finally determine a defect.

However, since the wiring is opened by manually scratching the circuit pattern in a defective cell, nondefective cells near the defective cell may also be undesirably scratched, which impairs the accuracy of operation. Furthermore, this manual operation can be time consuming.

### SUMMARY OF THE INVENTION

An aspect of the present invention provides a circuit board, and an apparatus for processing a defect in a circuit board, capable of realizing improved accuracy in detecting a defective cell by printing a short line in the main wiring of a defective cell in a circuit board by using an inkjet printing method.

According to an aspect of the present invention, there is provided a circuit board including: at least one non-defective cell including a non-defective circuit pattern; at least one defective cell including a defective circuit pattern; and a short line printed on the circuit pattern of the at least one defective cell.

The short line may be printed by an inkjet printing method.

The short line may be formed using a different ink from that of the circuit pattern.

The short line may be formed using ink comprising Ag, Au, Pt, Ni or Pd.

According to another aspect of the present invention, there is provided an apparatus for processing a defect in a circuit board, the apparatus including: a defective cell detection part detecting a defective cell among a plurality of cells including wiring patterns printed thereon, and creating data regarding coordinates of the defective cell; a defective cell indication part printing ink on the wiring pattern on the basis of the data regarding the coordinates of the defective cell, sent from the defective cell detection part, and thereby short-circuiting the defective cell; and a defective cell determination part classifying the defective cell, including the ink printed thereon, as a final defective cell.

The ink may be different from that used for the wiring pattern of the defective cell.

The ink may include Ag, Au, Pt, Ni or Pd.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a view illustrating a circuit board according to an exemplary embodiment of the present invention;

FIG. 2 is a view illustrating a defective cell on a circuit board according to an exemplary embodiment of the present invention;

FIG. 3 is an enlarged view of part A of FIG. 2; and

FIG. 4 is a block diagram illustrating an apparatus for processing a defect in a circuit board according to an exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. While those skilled in the art could readily devise many other varied embodiments that incorporate the teachings of the present invention through the addition, modification or deletion of elements, such embodiments may fall within the scope of the present invention.

The same or equivalent elements are referred to by the same reference numerals throughout the specification.

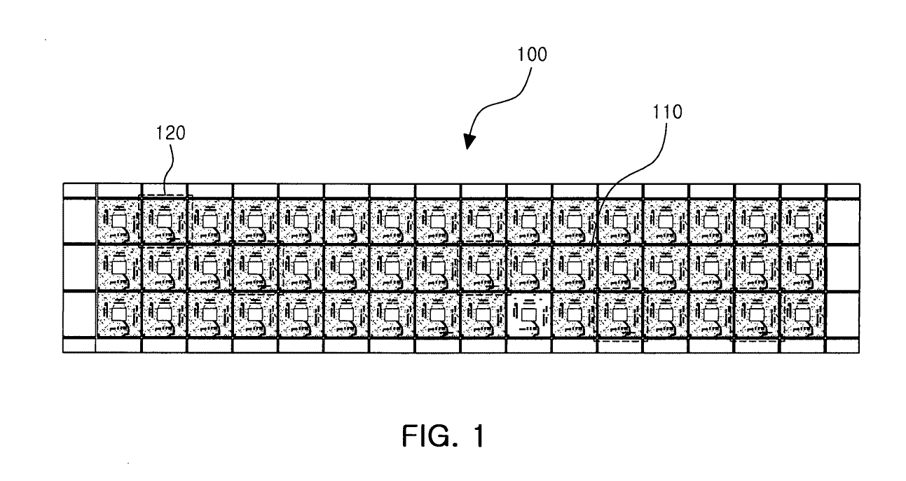

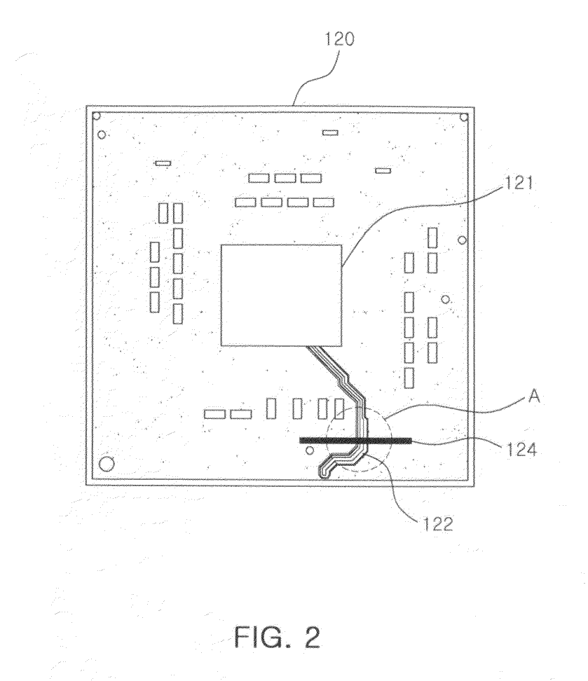

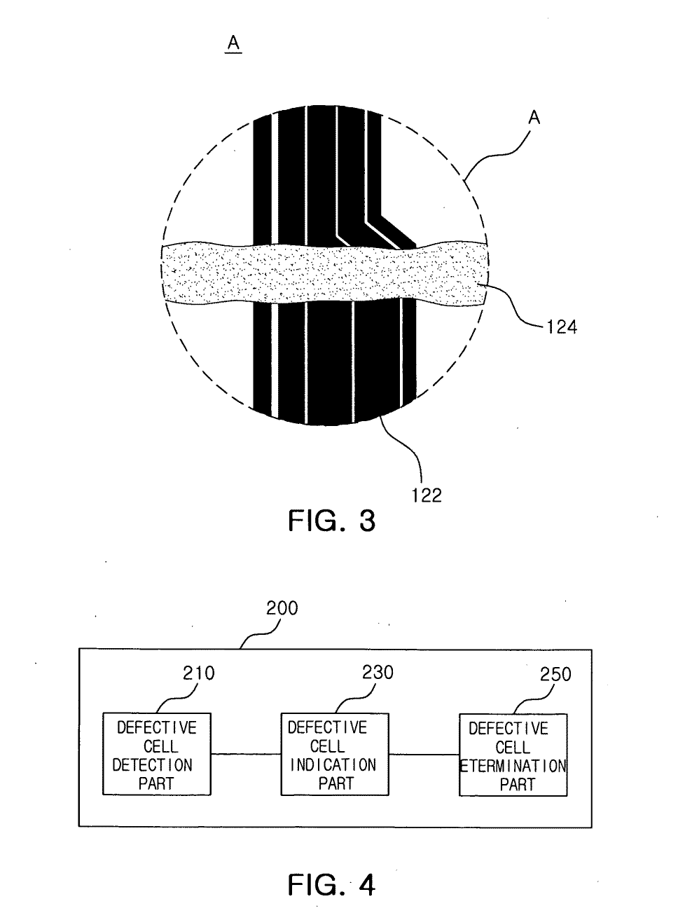

FIG. 1 is a view illustrating a circuit board according to an exemplary embodiment of the present invention. FIG. 2 is a view illustrating a defective cell on a circuit board according to an exemplary embodiment of the present invention. FIG. 3 is an enlarged view of part A of FIG.

A circuit board 100, according to an exemplary embodiment of the present invention, includes a plurality of cells 110 and 120 arranged into an m×n matrix. The cells 110 and 120 include various circuit components 121 mounted thereon, and circuit patterns are formed with regard to those components in order to constitute a circuit. The circuit patterns may be formed by printing conductive ink onto the circuit board 100. Here, the conductive ink may contain copper as the main component thereof.

With reference to FIG. 1, the plurality of cells 110 and 120 are arranged in a 3×16 matrix on the circuit board 100, and there are non-defective cells 110 and defective cells 120 among the plurality of cells thereon. In this exemplary embodiment, it is assumed that, in terms of (x, y) coordinates, a (2, 3) cell, a (4, 2) cell, a (9, 2) cell, a (12, 1) cell, and a (15, 1) cell are determined to be defective cells. The determination of defective cells 120 may be conducted by using an Automatic Optical Inspection (AOI) device.

Referring to FIGS. 2 and 3, a short line 124 is printed on the circuit pattern 122 of a cell, which is determined to be a defective cell 120 among the plurality of cells of the circuit board 100 shown in FIG. 1, for example, the circuit pattern 122 of the (2, 3) cell. The short line 124 may be printed by using an inkjet printer. Here, the short line 124 may be printed in a different direction from that of the circuit pattern 122 of the defective cell 120.

In this case, the ink, used to form the short line 124, may be a different kind of ink to that of the conductive ink that forms the circuit pattern 122. For example, the ink for the short line 124 may be any one of Ag, Au, Pt, Ni and Pd.

This is because the circuit pattern 122 of the circuit board 100 is printed using conductive ink containing copper. In detail, if the short line 124 is printed using ink consisting chiefly of copper, the short line 124 may be undesirably removed when etching is performed in order to remove copper undesirably formed on a portion other than the circuit pattern 122.

In this exemplary embodiment, the ink, used to form the short line 124, is not limited to the described material, and may utilize various kinds of conductive ink. In addition, when the conductive ink for the circuit pattern 122 does not contain copper, the short line 124 may be formed of the same kind of ink as the conductive ink.

FIG. 4 is a block diagram illustrating an apparatus for processing a defect in a circuit board according to an exemplary embodiment of the present invention. Hereinafter, the apparatus and process for processing defects in a circuit board will be described with reference to FIG. 4.

With reference to FIG. 4, an apparatus 200 for detecting a defect in a circuit board, according to an exemplary embodiment of the present invention, may include a defective cell detection part 210, a defective cell indication part 230, and a defective cell determination part 250.

The defective cell detection part 210 emits a laser beam onto a circuit pattern and analyzes a reflected image from the circuit pattern to thereby detect an open circuit pattern or a defective pattern width or length. Subsequently, the defective cell detection part 210 generates coordinate data concerning a cell having a defective circuit pattern, and sends the generated coordinate data to the defective cell indication part 230. The defective cell detection part 210 may be an Automated Optical Inspector (AOI).

The defective cell indication part 230 prints a short line on the primary circuit pattern of the defective cell on the circuit board on the basis of the coordinate data concerning the defective cell, sent from the defective cell detection part 210.

In detail, conductive ink is discharge onto the circuit pattern of the defective cell, thereby short-circuiting the circuit pattern. Therefore, the defective cell indication part 23 may be an inkjet printer.

The inkjet printer includes an inkjet print head (not shown) having an ink channel. The inkjet print head may, for example, be a piezoelectric inkjet print head. The piezoelectric inkjet print head has an ink channel in at least one substrate, and a piezoelectric actuator is provided on the upper portion of the substrate in order to provide a driving force for the discharge of ink.

The inkjet print head may include therein a manifold for transferring ink, introduced from an ink supply unit, to a plurality of pressure chambers along the ink channel, and a plurality of nozzles for discharging the ink onto the circuit pattern of a defective cell. Furthermore, the inkjet print head may include a plurality of restrictors configured to prevent the ink from flowing backwards from the pressure chambers toward the manifold when being discharged, and a plurality of dampers configured between the pressure chambers and the nozzles.

As the piezoelectric actuator, formed on the upper portion of the substrate to correspond to the pressure chamber, is driven, the upper portion of the substrate is deflected downwardly, and the volume of the pressure chamber decreases accordingly. In this manner, the pressure within the pressure chamber increases, thereby discharging ink within the pressure chamber onto the circuit pattern of a defective cell in a circuit board through the nozzle

As described above, the inkjet printer may be configured to discharge ink according to the piezoelectric driving method utilizing the piezoelectric actuator. However, the present invention is not limited by the mentioned ink discharge method, and ink may be discharged by using a variety of methods including a thermal driving method according to required conditions.

The ink, discharged from the defective cell indication part 230, may be formed of any one of Ag, Au, Pt, Ni and Pd. The reason why the above ink materials are utilized is to prevent a short line from being removed during etching, which is normally carried out in the process of manufacturing a circuit board in order to remove patterns formed mainly of copper and unnecessarily printed on part of the circuit board. In the case in which a short line is formed by using ink consisting chiefly of copper, the copper etching may undesirably remove part of the short line. In this case, the defective cell determination part 250 may erroneously determine the defective cell to be a non-defective cell.

The defective cell determination part 250 performs E-checking upon the circuit board by using a test probe, thereby classifying the cell including the circuit pattern with the short line printed thereon, as a final defective cell. For example, the final defective cell may be determined by measuring electrical characteristics, such as the electric conductivity of a circuit pattern, or an image of a circuit pattern.

The defective cell determination part 250 may receive data regarding the coordinates of the defective cell detected by the defective cell detection part 210, and determine the defective cell on the basis of the received data. Besides, the defective cell determination part 250 may be used to detect a defect caused during other operations of the process of manufacturing a circuit board, and determine a corresponding cell as a defective cell.

The process of processing a defective cell, performed using the apparatus 200 for processing a defective cell in a circuit board, will now be described in a sequential order. First, a circuit board is transferred to the defective cell detection part 210.

The defective cell detection part 210 detects a defective cell, having an open circuit pattern, a defective pattern width or length or the like, from the transferred circuit board.

Subsequently, the defective cell detection part 210 creates data regarding the coordinates of the detective cell, and sends the data to the defective cell indication part 230. Thereafter, the circuit board is transferred to the defective cell indication part 230.

The defective cell indication part 230 prints a short line on the circuit pattern of the detective cell in the transferred circuit board by using an inkjet printing method.

The short line may be printed on the defective cell under the following conditions: metallic ink, having a metal weight percent ranging from 30% to 50% and containing a solvent formed chiefly of aqueous or non-aqueous silver nanoparticles, may be used, a piezoelectric inkjet print head adopting 256 nozzles may be used, a printing temperature may range from 50° C. to 60° C. in order to prevent the spread of ink and ensure sufficient thickness, a printing resolution may range from 500 DPI to 5000 DPI, and a printing speed may range from 50 mm/s to 300 mm/s.

After the short line is printed by the inkjet printing, the solvent of the ink, forming the short line, is evaporated, the aggregation of nanoparticles and the grain growth are accelerated, and the resultant material is subjected to a heat treatment to thereby exhibit conductivity.

Meanwhile, the process of manufacturing a circuit board includes the curing of Ajinimoto Build-up Film (ABF) resin, which is an insulator. According to the present invention, the sintering of the short line is carried out simultaneously with this curing process. Accordingly, the short line can be performed through a single process without undergoing a separate heat treatment. In this case, the sintering is performed at a temperature range of 150° C. to 200° C. in an air or nitrogen atmosphere for 0.5 to 1 hour.

The circuit board printed and sintered in the above manner is transferred to the defective cell determination part 250, and the defective cell determination part 250 determines the defective cell to be a final detective cell.

As set forth above, in the circuit board and the detect processing apparatus for a circuit board according to exemplary embodiments of the invention, a short line is printed on the main wiring of a detective cell in a circuit board, thereby enhancing the accuracy of detecting a defective cell.

While the present invention has been shown and described in connection with the exemplary embodiments, it will be apparent to those skilled in the art that modifications and variations can be made without departing from the spirit and scope of the invention as defined by the appended claims. For example, it should be construed that using an AOI device to detect a defective cell is exemplified and a configuration for determining a final detective cell may also be performed by a variety of methods other than the E-checking. Furthermore, different driving methods and different types of inkjet print head may be utilized in order to indicate a defective cell using an inkjet printing method.

What is claimed is:

1. A circuit board comprising:
at least one non-defective cell including a non-defective circuit pattern;
at least one defective cell including a defective circuit pattern; and
a short line printed on the circuit pattern of the at least one defective cell.

2. The circuit board of claim 1, wherein the short line is printed by an inkjet printing method.

3. The circuit board of claim 1, wherein the short line is formed using a different ink from that of the circuit pattern.

4. The circuit board of claim 1, wherein the short line is formed using ink comprising Ag, Au, Pt, Ni or Pd.

5. An apparatus for processing a defect in a circuit board, the apparatus comprising:
a defective cell detection part detecting a defective cell among a plurality of cells including wiring patterns printed thereon, and creating data regarding coordinates of the defective cell;
a defective cell indication part printing ink on the wiring pattern on the basis of the data regarding the coordinates of the defective cell, sent from the defective cell detection part, and thereby short-circuiting the defective cell; and
a defective cell determination part classifying the defective cell, including the ink printed thereon, as a final defective cell.

6. The apparatus of claim 5, wherein the ink is different from that used for the wiring pattern of the defective cell.

7. The apparatus of claim 5, wherein the ink comprises Ag, Au, Pt, Ni or Pd.
